(19) United States
(12) Patent Application Publication
(10) Pub. No.: US 2011/0157793 A1
(43) Pub. Date: Jun. 30, 2011

(54) SLIDE-TYPE ELECTRONIC DEVICE

(75) Inventors: XIAN-WEI MA, Shenzhen City (CN); TING LUO, Shenzhen City (CN)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/940,037

(22) Filed: Nov. 4, 2010

(30) Foreign Application Priority Data
Dec. 30, 2009 (CN) 200910312752.0

(51) Int. Cl. H05K 7/00

(52) U.S. Cl. 361/679.01

(57) ABSTRACT

An electronic device includes a main body mounting an input unit, a lid mounting a display, and a slide mechanism connecting the lid to the main body. The slide mechanism includes a first support member and a second support member. The first support member includes a first arm and a first rod secured to each other. The first rod is movably connected to the main body. The second support member includes a second arm and a second rod secured to each other. The second arm is pivotally connected to the first arm, and the second rod is movably connected to the main body. The lid is connected to the first support member or the second support member.

### BACKGROUND

1. Technical Field

The present disclosure relates to slide-type electronic devices, and particularly to a slide-type electronic device capable of adjusting the orientation of a display.

2. Description of the Related Art

A conventional slide-type electronic device includes a main body and a lid slidably connected to the main body with a slide mechanism. In these slide-type electronic devices, the lid moves toward the direction parallel to the main body but cannot move to a position where the lid is tilted toward the main body to provide a better view angle.

### BRIEF DESCRIPTION OF THE DRAWINGS

The components of the drawings are not necessarily drawn to scale, the emphasis instead being placed upon clearly illustrating the principles of a slide-type electronic device. Moreover, in the drawings, like reference numerals designate corresponding parts throughout several views.

FIG. 1 is an isometric view of an electronic device according to an exemplary embodiment, showing the device in a closed position.

FIG. 2 is another isometric view of the electronic device of FIG. 1, showing the device in an open position.

FIG. 3 is a partial, exploded, perspective view of the electronic device of FIG. 1.

FIG. 4 is a cross-sectional view of the electronic device of FIG. 1, taken along line IV-IV of FIG. 2.

FIG. 5 is an enlarged view of the portion V of FIG. 4.

FIG. 6 is a partial, perspective view of the electronic device of FIG. 1, showing a slide mechanism of the electronic device in a first position.

FIG. 7 is similar to FIG. 6, but showing the slide mechanism in a second position.

FIG. 8 is similar to FIG. 6, but showing the slide mechanism in a third position.

### DETAILED DESCRIPTION

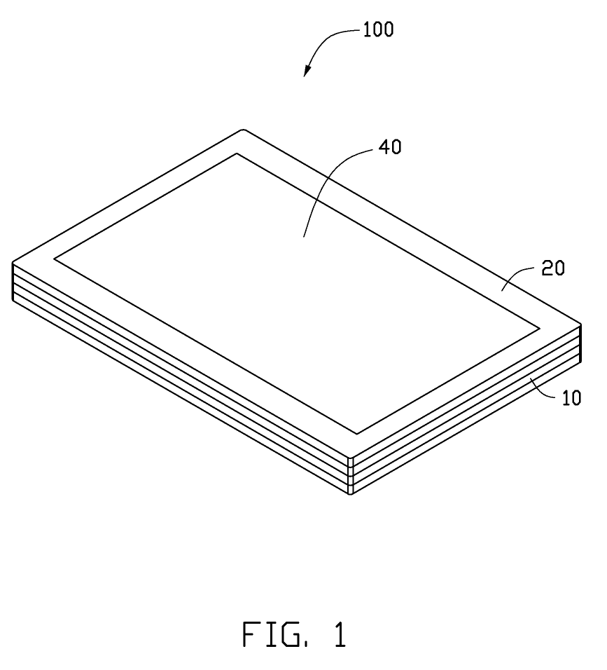

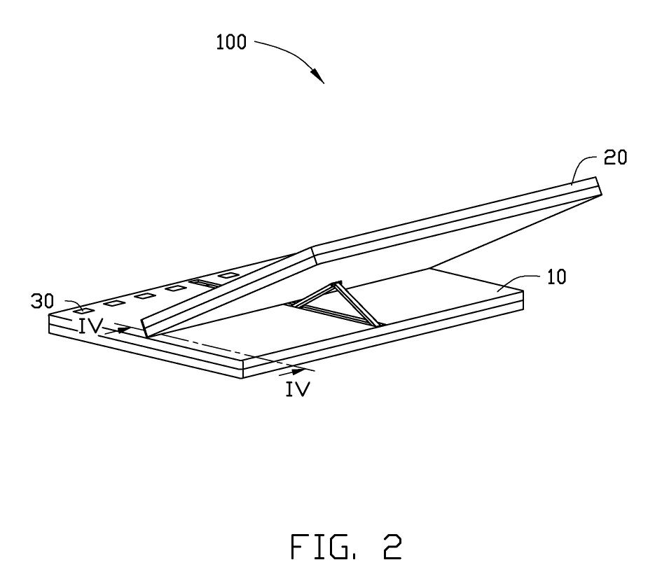

Referring to FIGS. 1 and 2, a slide-type electronic device 100 according to an exemplary embodiment is illustrated. The electronic device 100 includes a main body 10, a lid 20, and a slide mechanism 50. The lid 20 is slidably connected to the main body 10 with the slide mechanism 50. The main body 10 includes an input unit 30 for users to input information to the electronic device 100. In this embodiment, the input unit 30 is a keypad. The lid 20 includes a display 40. In the embodiment, the device 10 is a portable computer. In alternative embodiments, features of the embodiment could be used in any suitable type of hand-held portable electronic device such as a mobile phone, a music player, or a PDA.

The lid 20 can be moved between a closed position (see FIG. 1) and an open position (see FIG. 2) with the slide mechanism 50. The display 40 is visible when the device 100 is in either the closed position or the open position. In the closed position, the lid 20 covers the input unit 30. In the open position, the lid 20 is tilted toward the main body 10 to allow for a better view of the display 40.

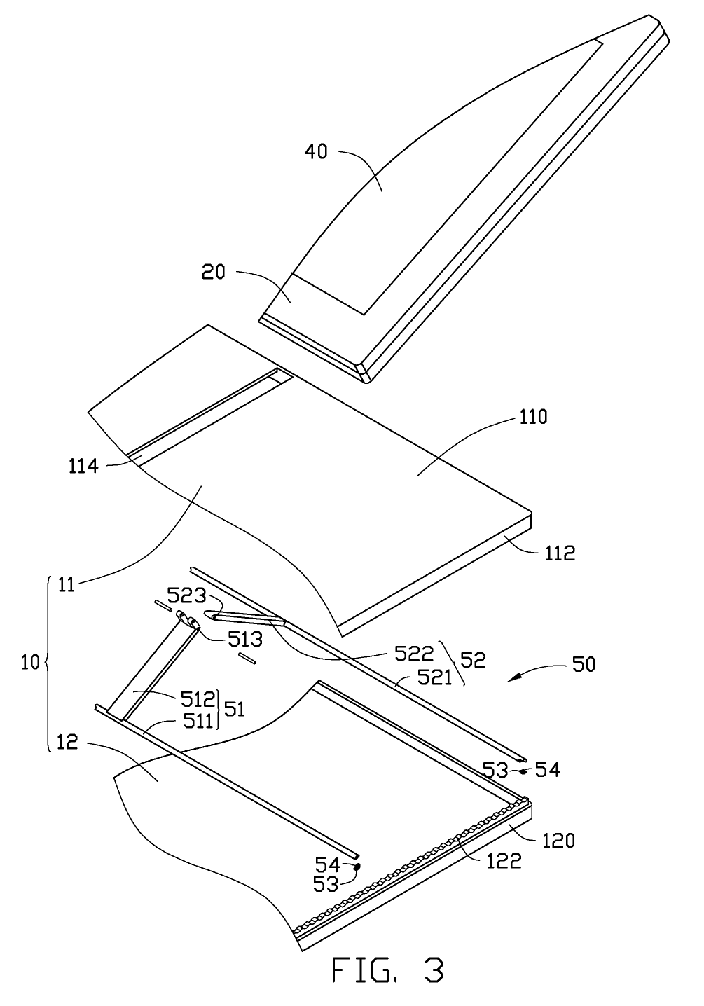

Referring to FIG. 3, the main body 10 includes a first cover 11 and a second cover 12 cooperatively forming an interior space to accommodate electronic elements. The first cover 11 includes a top surface 110 and two parallel first sidewalls 112 (one not seen) respectively extending from opposite ends of the top surface 110 and substantially perpendicularly to the top surface 110. The top surface 110 defines a slide slot 114 arranged between the first sidewalls 112. In the embodiment, the slide slot 114 extends substantially parallel to the first sidewalls 112 and is arranged in the middle of the first cover 11. The second cover 12 includes two parallel second sidewalls 120 (one not seen) coupled to the first sidewalls 112 to attach the second cover 12 to the first cover 11. A top end of each of the second sidewalls 120 defines a plurality of recesses 122 opposite to the first cover 11. The recesses 120 are connected one by one to form a wave-shaped and elongated surface.

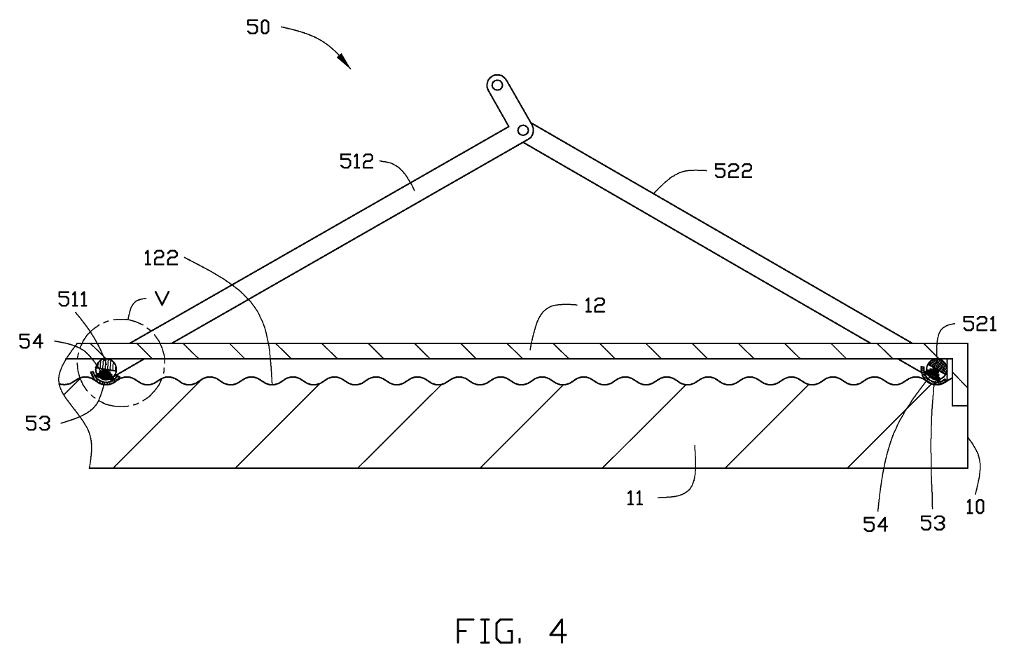

Referring to FIGS. 3 and 4, the slide mechanism 50 includes a first support member 51 and a second support member 52 moveably connected to the main body 10. The first support member 51 includes a first rod 511 and a first arm 512 perpendicularly secured to the first rod 511. Two blocks 513 extend perpendicularly from a free end of the first arm 512 and are substantially parallel to each other. The second support member 52 includes a second rod 521 and a second arm 522 perpendicularly secured to the second arm 522. The first rod 511 and the second rod 521 are movably received in the main body 10 and substantially perpendicular to the slide slot 114. The first arm 512 and the second arm 522 can be received in the slide slot 114. A free end of the second arm 522 is pivotally connected to bottom ends of the blocks 513. The lid 20 is pivotally connected to top ends of the blocks 513.

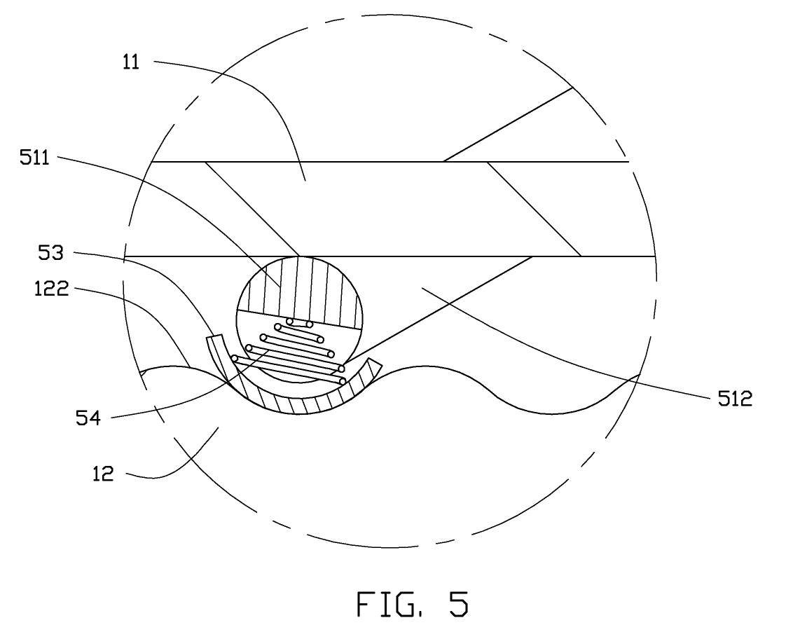

Referring also to FIG. 5, the slide mechanism 50 further includes four clips 53 and four resilient members 54 each with an end attached to an end of the first rod 511 or the second rod 512 and an opposite end attached to one clip 53. The clips 53 are substantially arc-shaped, and the clip 53 can be received in one of the recesses 122. In this embodiment, the resilient members 54 are helical springs. When the lid 20 is pushed, the first rod 511 and the second rod 521 are driven to slide along a direction parallel to the slide slot 114, thus causing the clips 53 to slide along the recesses 122. While the clips 53 are driven out of the recesses 122, the resilient members 54 are compressed.

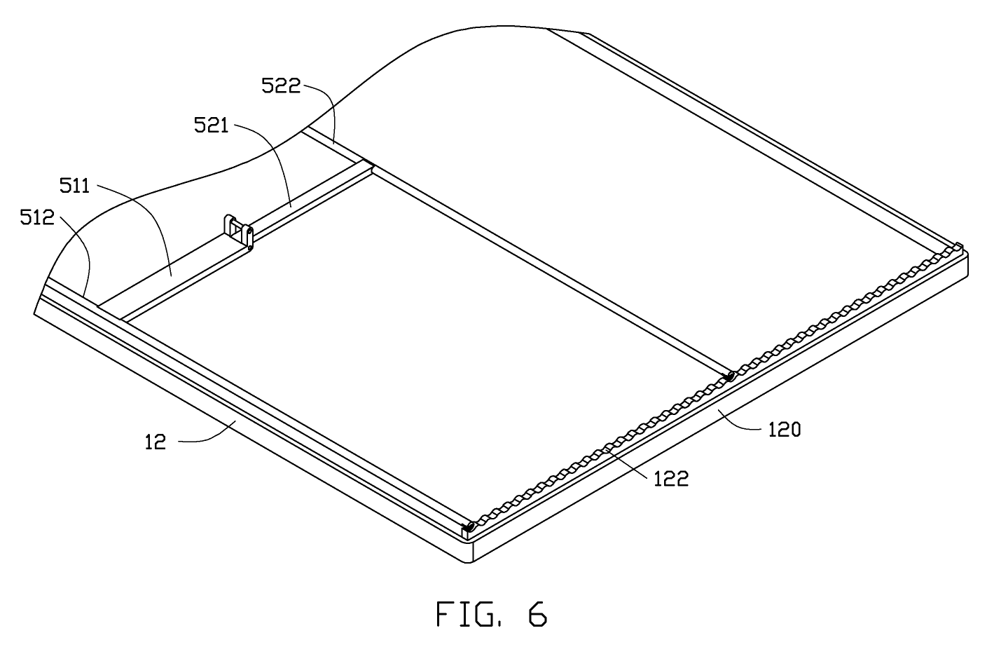

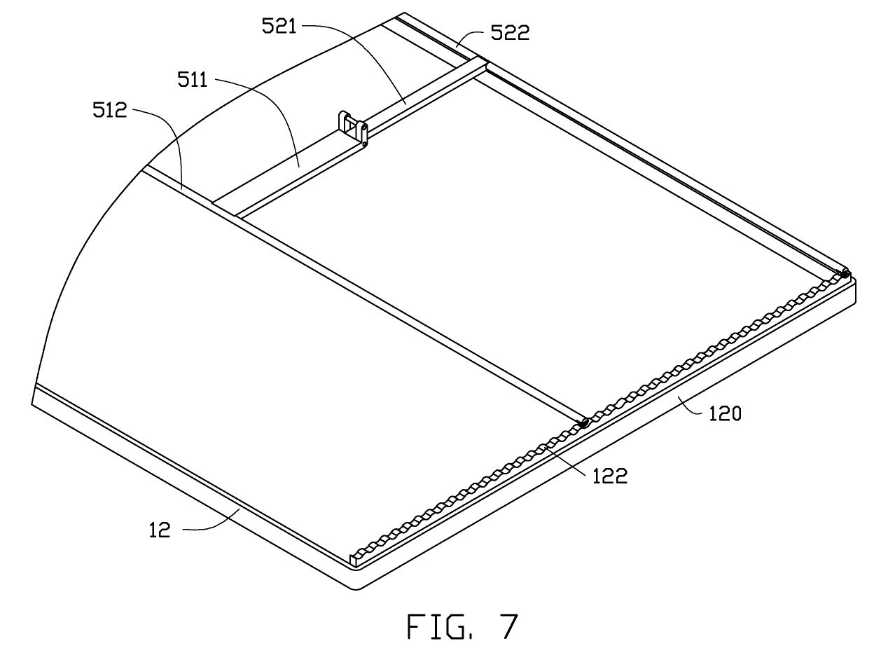

FIG. 6 shows the slide mechanism 50 in a first position where the lid 20 covers the input unit 30. FIG. 7 shows the slide mechanism 50 is pushed to a second position where the input unit 30 is exposed and the lid 20 is parallel to the main body 10.

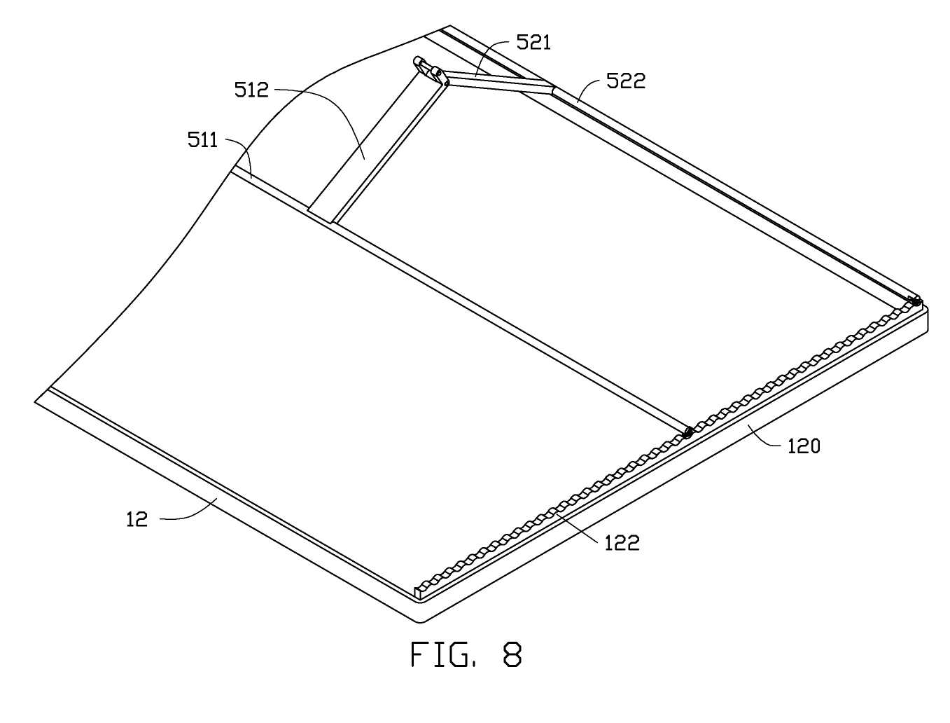

FIG. 8 shows the slide mechanism 50 is further pushed to a third position where the lid 20 is tilted toward the main body 20 with the first support member 51 and a second support member 52 pivotally forming an angle greater than zero and less than 180 degrees. In this position, if the slide mechanism 50 is released, the resilient members 54 rebound to drive each of the clips 53 to be received in one of the recesses 122 to keep the lid 20 to be in the open position.

Although the present disclosure has been specifically described on the basis of certain embodiments thereof, the disclosure is not to be construed as being limited to the described embodiments. Various changes or modifications may be made to the embodiments without departing from the scope and spirit of the disclosure.

What is claimed is:

1. An electronic device comprising:
a main body;
a lid; and
a slide mechanism comprising:
a first support member comprising a first arm and a first rod secured to the first arm, wherein the first rod is movably connected to the main body, and the lid is pivotally connected to the first arm; and
a second support member comprising a second arm and a second rod secured to the second arm, wherein the second arm is pivotally connected to the first arm, the second rod is movably connected to the main body;
wherein, when the slide mechanism is pushed to a position where the first arm and the second arm defines an angle greater than zero and less than 180 degrees, the lid is pushed to a position where the lid is tilted toward the main body.

2. The electronic device as described in claim 1, wherein the main body comprises an input unit, and the lid comprises a display opposite to the input unit.

3. The electronic device as described in claim 1, wherein the main body comprises a first cover and a second cover, the first cover comprises two parallel first sidewalls, and the second cover comprises two parallel second sidewalls coupled to the first walls.

4. The electronic device as described in claim 3, wherein a top end of each of the second sidewalls defines a plurality of recesses opposite to the first cover, the recesses are connected one by one to form a wave-shaped and elongated surface, the slide mechanism comprises a plurality of clips and a plurality of resilient members, each of opposite ends of the first rod is attached to one of the resilient members, each of opposite ends of the second rod is attached to one of the resilient members, each of the resilient members are further attached to one of the clips, each of the clips are received in one of the recesses.

5. The electronic device as described in claim 4, wherein the first arm is substantially perpendicular to the first rod, and the second arm is substantially perpendicular to the second rod, the first cover defines a sliding slot arranged between the first sidewalls, the first arm and the second arm are able to be received in the sliding slot.

6. The electronic device as described in claim 5, wherein two blocks away from the first rod protrude from an end of the first arm, the second arm is pivotally connected to bottom ends of the blocks, and the lid is pivotally connected to top ends of the blocks.

7. The electronic device as described in claim 4, wherein the resilient members are helical springs.

8. The electronic device as described in claim 4, wherein the recesses and the clips are substantially arc-shaped.

9. An electronic device, comprising:
a main body comprising a first cover and a second cover, the first cover comprising two parallel first sidewalls, the second cover comprising two parallel second sidewalls coupled to the first sidewalls, the first cover defining a sliding slot arranged between and substantially parallel to the first sidewalls, a top end of each of the second sidewalls defining a plurality of recesses opposite to the first cover, the recesses are connected one by one to form a wave-shaped and elongated surface;
a lid; and
a slide mechanism comprising:
a first support member comprising a first arm and a first rod substantially perpendicular to and secured to the first arm, the first rod is movably connected to the main body, the first arm is able to be received in the sliding slot, the lid is pivotally connected to a first end of the first arm; and
a second support member comprising a second arm and a second rod substantially perpendicular to and secured to the second arm, the second arm is pivotally connected to the first end of the first arm and arranged below lid, the second rod is movable connected to the main body;
a plurality of resilient members, each of opposite ends of the first rod being attached to one of the resilient members, each of opposite ends of the second rod being attached to one of the resilient members; and
a plurality of clips, each of the clips being attached to one of the resilient members, and each of the clips being received in one of the recesses;
wherein, when the slide mechanism is pushed to a position where the first arm and the second arm defines an angle greater than zero and less than 180 degrees, the lid is pushed to a position where the lid is tilted toward the main body, and each of the clips are received in one of the recesses to keep the lid to be in the position.
